(19) United States
(12) Patent Application Publication
(10) Pub. No.: US 2003/0077911 A1
(43) Pub. Date: Apr. 24, 2003

(54) Rom code mask with assistant features

(76) Inventors: Ching-Yu Chang, I Lan Hsien (TW); I-Pien Wu, Hsin-Chu City (TW); Chi-Yuan Hung, I-Lan Hsien (TW)

Correspondence Address: NAIPO (NORTH AMERICA INTERNATIONAL PATENT OFFICE), P.O. BOX 506, MERRIFIELD, VA, 22116, US

(21) Appl. No.: 09/682,808

(22) Filed: Oct. 22, 2001

(51) Int. Cl. H01L 21/302; H01L 21/461

(52) U.S. Cl. 438/725

(57) ABSTRACT

A method of forming a pattern according to a set of ROM codes in a photoresist layer is performed on a wafer coated with a photoresist layer. A projection lens is positioned atop a top surface of the wafer. An exposure light source having a pre-selected wavelength for generating a dipole exposure ray is provided. And a ROM code mask is positioned between the projection lens and the exposure light source. The ROM code mask has a plurality of ROM code openings arranged in a non-periodic manner and a plurality of assistant features arranged among the plurality of ROM code openings. The assistant features function as image enhancement elements that render a combined pattern consisting of the plurality of ROM code openings and the plurality of assistant features that are substantially periodic along an x-axis.

### BACKGROUND OF THE INVENTION

1. Field of the Invention

The present invention relates to a method of semiconductor fabrication, and more particularly, to a method of performing a photolithographic process applied in creating a ROM code pattern on a photoresist layer.

2. Background of the Invention

A read-only memory (ROM) is a semiconductor device that comprises a plurality of memory cells for storing data. Each of the memory cells comprises a MOS transistor. The data held in the circuits of a ROM does not change in either power off or power on conditions. Consequently, the data stored in the ROM are not lost if the power is turned off. This is also why the ROM can only be read.

A general method of forming a ROM involves arranging a plurality of MOS transistors in a matrix format on a predetermined area of a die. These MOS transistors are regarded as the memory cells for storing data. Some of them are enabled to indicate one binary state, whereas others are disabled to indicate the opposite binary state. To arrange these memory cells, a mask is formed according to a set of ROM codes to be written into the ROM. Then, the pattern on the mask is transferred to the ROM by performing a photolithography process. Therefore, the set of ROM codes is written into the ROM correctly, and the ROM, which is formed from a mask, is called Mask ROM. A method of writing a set of ROM codes into the ROM is to implant ions into the channel of the MOS transistor to modify the threshold voltage of the MOS transistor. In addition, a process of writing a set of ROM codes into the ROM is called a ROM code implantation process.

Please refer to FIG. 1. FIG. 1 is a top view of a mask ROM array structure 10. The mask ROM array structure 10 comprises a plurality of bit lines 12, and a plurality of word lines 14 arranged vertically across the bit lines 12. The bit lines 12 and the word lines 14 form memory cell transistors 16 in a matrix format in the mask ROM. A channel 18 in the memory cell transistor 16 is a position into which ROM codes are written. Wherein the bit lines 12 serve as source and drain of the memory cell transistors 16 and the word lines 14 serve as gates of the memory cell transistors 16.

After completing formation of the bit lines 12 and the word lines 14 in the mask ROM array structure 10, the ROM code implantation process is performed. At first, a photoresist layer is coated onto the surface of the mask ROM array structure 10. Then, a photolithography system (not shown here), which at least comprises a light source, a mask formed according to a set of ROM codes, and a projection lens, is utilized to create a ROM code pattern in the photoresist layer. Then, portions of the memory cell transistors 16 in the mask ROM array structure 10, intended to be implanted with ions, are defined. Finally, an ion implantation process is performed. Please refer to FIG. 2. FIG. 2 is a schematic diagram of a mask 20 formed according to a set of ROM codes. The mask 20 comprises a plurality of openings 22. The arrangement of the openings 22 depends on the corresponding set of ROM codes. The size of the openings 22 and a distance between the openings 22 depend on a process demand.

Because a density of integrated circuits is increasing, the distance between the openings 22 in the mask 20 becomes closer. As a result, diffraction effects caused by light passing through the openings 22 in the mask 20, a so-called optical proximity effect, are more and more obvious. A resolution loss of the pattern in the photoresist layer is one problem caused by the optical proximity effect, which leads to incorrectly transferring the ROM code pattern from the mask 20 to the mask ROM array structure 10. Please to FIG. 3. FIG. 3 is a top view of a defined mask ROM array structure 30. The defined mask ROM array structure 30 comprises a plurality of bit lines 32, a plurality of word lines 34 arranged vertically across the bit lines 32, and a photoresist layer (not shown here) covering the bit lines 32 and the word lines 34. “Defined” implies that the ROM code pattern on the mask 20 is transferred to the photoresist layer by utilizing a photolithography system comprising the mask 20. Wherein region A, region B, region C, region D and region E are portions intending to be implanted with ions. As shown in FIG. 2 and FIG. 3, because the distance between the openings 22 in the mask 20 becomes close, diffraction effects caused by light passing through the openings 22 in the mask 20, a so-called optical proximity effect, are obvious. Due to the optical proximity effect, the pattern in the mask 20 formed according to a set of ROM codes cannot be correctly transferred to the photoresist layer on the defined mask ROM array structure 30D. Additionally, isolated region C does not form in the photoresist layer on the defined mask ROM array structure 30 due to insufficient exposing intensity. As shown in FIG. 3, region A, region B, region D and region E are all across the bit lines 32. As a result, when performing ROM code implantation, ions are implanted into channels of transistors as well as into the bit lines 32, which leads to non-uniform sheet resistivity of the bit lines 32. Therefore, sheet resistivity of source/drain in the memory cell transistors is non-uniform, which seriously affects the electrical performance of memory cell transistors. In addition, a lack of region C in the photoresist layer causes ROM codes not to be implanted into the channels of the transistors, which results in incorrectly writing data in the mask ROM.

Prior methods used to solve the above-mentioned problems include utilizing two mask or phase shift mask (PSM) lithographic technology, adapting light sources with lower wavelengths (such as 193 nm), and utilizing optical proximity correction (OPC), etc. However, all of the above-mentioned methods have several limitations. Utilizing two mask lithographic technology results in a high cost and a low throughput. When utilizing PSM lithographic technology, a cost for making a mask is high and a lot of defects in the mask areinevitable. Additionally, development of the light source with the wavelength of 193 nm is not maturing. The software of OPC is expensive, time expended in running the software is long, and a process window is insufficient. As a result, it is necessary to develop a more efficient and low cost method to solve the above-mentioned problems.

### SUMMARY OF THE INVENTION

It is therefore a primary objective of the present invention to provide a method of forming a pattern according to a set of ROM codes in a photoresist layer that reduces resolution loss, and is efficient and low cost.

Briefly, the method of the claimed invention is performed on a wafer coated with a photoresist layer. A projection lens is positioned atop a top surface of the wafer. An exposure light source having a pre-selected wavelength for generating a dipole exposure ray is provided. And, a ROM code mask is positioned between the projection lens and the exposure light source, wherein the ROM code mask comprises a plurality of ROM code openings arranged in a non-periodic manner, and a plurality of assistant features arranged among the plurality of ROM code openings, and wherein the assistant features function as image enhancement elements that render a combined pattern consisting of the plurality of ROM code openings and the plurality of assistant features that are substantially periodic along an x-axis.

It is an advantage of the present invention that it utilizes the mask and a dipole illumination to enhance the x-axis resolution and reduce the optical proximity effect when transferring the ROM code pattern from the mask to the photoresist layer. Wherein the mask has the ROM code openings and assistant features that form periodic patterns in the mask. As a result, the non-uniformity of sheet resistivity of the bit lines can be solved. In addition, adding assistant features in both sides of the ROM code openings can enhance formation of the image of the ROM code openings in the photoresist layer. As a result, that the image of isolated openings cannot form in the photoresist layer due to insufficient exposing intensity is solved. The difference between the image of isolated openings and the image of dense openings is reduced. Further, a problem of incorrectly writing data in the mask ROM is solved.

These and other objectives and advantages of the present invention will no doubt become obvious to those of ordinary skill in the art after having read the following detailed description of the preferred embodiment that is illustrated in the various figures and drawings.

### BRIEF DESCRIPTION OF DRAWINGS

FIG. 1 is a top view of a mask ROM array structure.

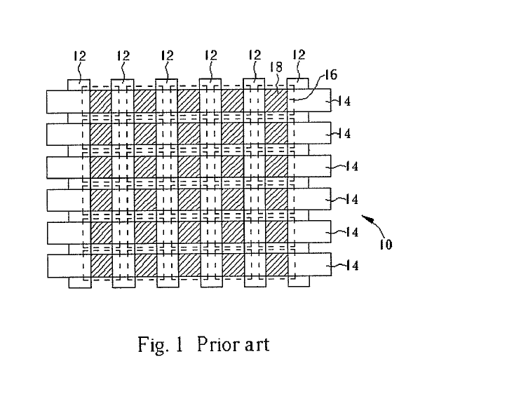

FIG. 2 is a schematic diagram of a mask formed according to a set of ROM codes.

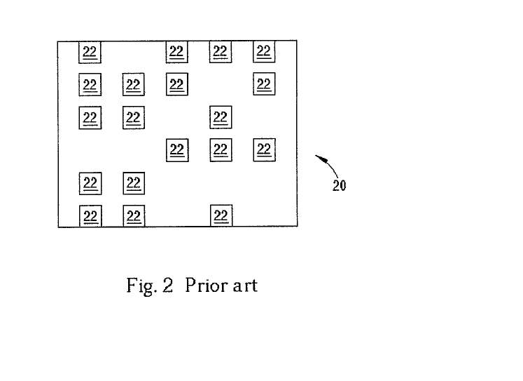

FIG. 3 is a top view of a defined mask ROM array structure.

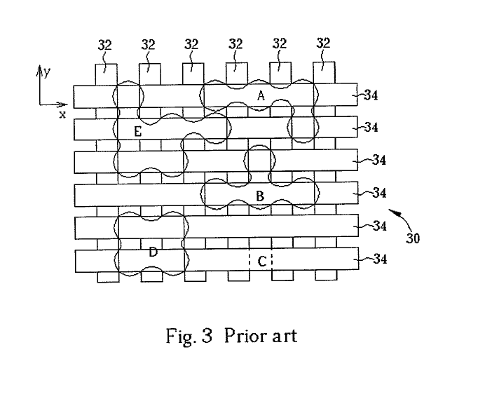

FIG. 4 is a simplified structural schematic diagram of a photolithography system according to the preferred embodiment in the present invention.

FIG. 5(A) is a top view of a mask shown in FIG. 4.

FIG. 5(B) is a top view of the mask shown in FIG. 4 according to another embodiment of the present invention.

FIG. 6 is a top view of an aperture plate shown in FIG. 4.

FIG. 7 is a top view of a defined mask ROM array structure.

### DETAILED DESCRIPTION

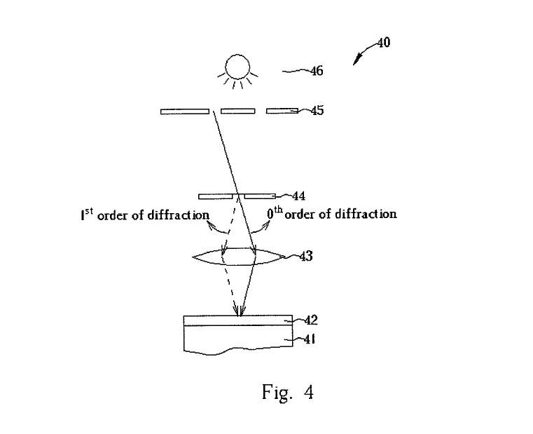

Please refer to FIG. 4. FIG. 4 is a simplified structural schematic diagram of a photolithography system 40 according to the preferred embodiment in the present invention. As shown in FIG. 4, the photolithography system 40 at least comprises a semiconductor wafer 41, a photoresist layer 42 coated on the semiconductor wafer 41, a projection lens 43 positioned atop the top surface of the semiconductor wafer 41, a mask 44 formed according to a set of ROM codes positioned atop the projection lens 43, an aperture plate 45 positioned atop the mask 44, and a light source 46 positioned atop the aperture plate 45. In the preferred embodiment of the present invention, the light source 46 utilizes a light with wavelength of 248 nm. In another embodiment of the present invention, the light source 46 utilizes a light with wavelength of 193 nm or 157 nm. Light produced from the light source 46 passes through the aperture plate 45, projects onto the mask 44 and, then, forms diffraction. A 0^{th} order of diffracted light and a 1^{st} order of diffracted light are collected by the projection lens 43 with a numerical aperture (NA) larger than 0.4, and, then, form an image in the photoresist layer 42. An exposing process is therefore completed. Then, developing, cleaning and etching processes are performed to transfer a ROM code pattern from the mask 44 onto the semiconductor wafer 41. Because developing, cleaning and etching processes are known to those skilled in this art, the details are not discussed further.

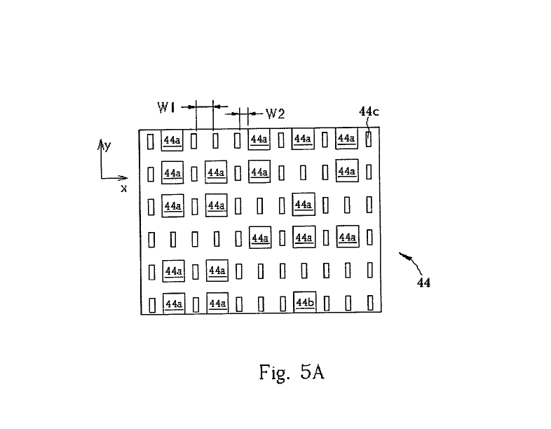

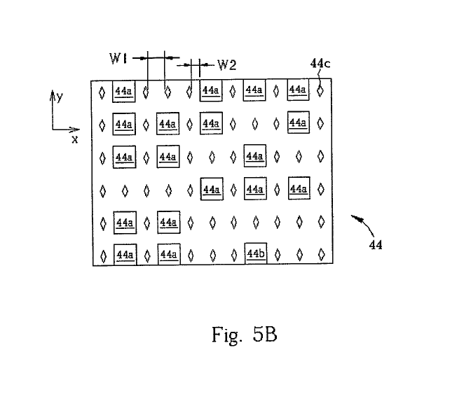

Please refer to FIG. 5(A). FIG. 5(A) is a top view of the mask 44 shown in FIG. 4. The mask 44 comprises a plurality of ROM code openings 44a, a plurality of ROM code openings 44b, and a plurality of assistant features 44c arranged among the pluralities of ROM code openings 44a and 44b. The assistant features 44c in the mask 44 are substantially periodic along an x-axis in order to enhance the resolution of the ROM code pattern in the photoresist layer 42. Additionally, adding assistant features 44c in both sides of the ROM code openings 44b can enhance formation of the image of the ROM code openings 44b in the photoresist layer 42. As a result, the image of isolated openings can now form in the photoresist layer 42. The difference between the image of isolated openings and the image of dense openings is also reduced.

Noticeably, the assistant features 44c have a dimension such that no corresponding image is formed on the photoresist layer 42 after light passes through the assistant features 44c. Therefore, the assistant features 44c do not affect transferal of the ROM code pattern from the mask 44 onto the photoresist layer. In the preferred embodiment of the present invention, a distance between the assistant features 44c is indicated as w₁ and a distance between the assistant features 44c and the ROM code openings 44a is indicated as w₂. Both w₁ and w₂ are between λ/2 and 2λ, where λ is a wavelength of the light source 46. Please refer to FIG. 5(B). FIG. 5(B) is a top view of the mask 44 shown in FIG. 4 according to another embodiment of the present invention. Noticeably, both in FIG. 5(A) and FIG. 5(B), patterns in the mask 44 are periodic along an x-axis.

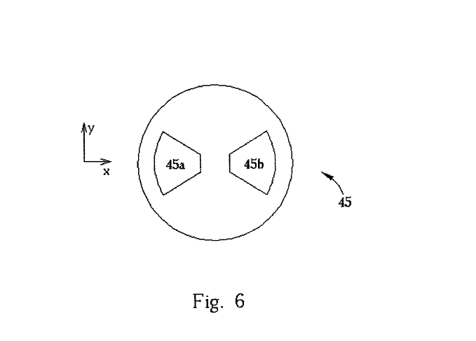

Please refer to FIG. 6. FIG. 6 is a top view of the aperture plate 45 shown in FIG. 4. The aperture plate 45 comprises an opening 45a and an opening 45b. The opening 45a and the opening 45b function to produce off-axis illumination, which is called a dipole illumination. One characteristic of the dipole illumination is enhancing resolution of the image formed in the photoresist layer, wherein the image is produced by a photolithography system comprising a mask with periodic patterns along one axis. As a result, the present invention applies the characteristic of the dipole illumination to solve problems of resolution loss. Adding the assistant features 44c in the mask 44 makes patterns in the mask 44 substantially periodic along an x-axis. Additionally, combining with dipole illumination solves the problem of the resolution loss along an x-axis. The present invention is not limited to the aperture plate 45 shown in FIG. 6. Any kinds of aperture plate that produce dipole illumination can be utilized in the present invention.

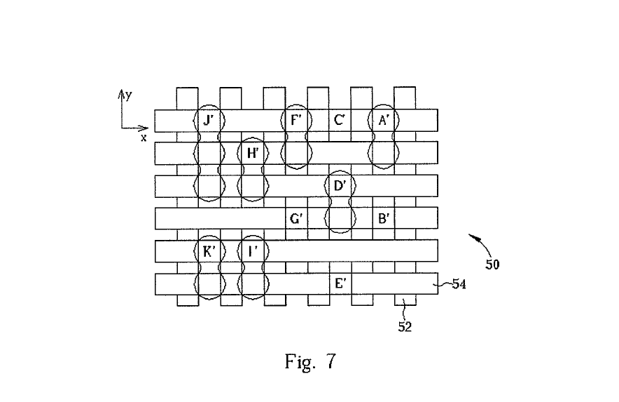

Please refer to FIG. 7. FIG. 7 is a top view of a defined mask ROM array structure 50. The defined mask ROM array structure 50 comprises a plurality of bit lines 52, a plurality of word lines 54 arranged vertically across the bit lines 52, and a photoresist layer (not shown here) covering the bit lines 52 and the word lines 54. “Defined” implies that the ROM code pattern on the mask 44 is transferred to the photoresist layer by utilizing a photolithography system 40. Wherein region A, region B, region C, region D, region E, region F, region G, region H, region 1, region J and region K are portions to be implanted with ions. As shown in FIG. 7, region A″˜ region K all are not arranged across the bit lines 52. As a result, the method in the present invention can enhance the x-axis resolution.

The present invention utilizes the mask 44 and a dipole illumination produced by the aperture plate 45 to enhance the x-axis resolution and reduce the optical proximity effect when transferring the ROM code pattern from the mask 44 to the photoresist layer 42. Wherein the mask 44 has the ROM code openings 44a, ROM code openings 44b and assistant features 44c that form periodic patterns in the mask 44. Further, the non-uniformity of sheet resistivity of the bit lines 52 can be solved. In other words, the non-uniformity of sheet resistivity of source/drain of memory cell transistors, which affects the electrical performance of the memory cell transistors, can be improved.

In addition, adding assistant features 44c in both sides of the ROM code openings 44b can enhance formation of the image of the ROM code openings 44b in the photoresist layer 42. As a result, that the image of isolated openings cannot form in the photoresist layer 42 due to insufficient exposing intensity is solved. The difference between the image of isolated openings and the image of dense openings is reduced. Further, a problem of incorrectly writing data in the mask ROM is solved. Furthermore, the characteristic of the present invention is utilizing only one mask to solve the above-mentioned problems and reduce production cost and enhance process efficiency.

The above disclosure is based on the preferred embodiment of the present invention.

Those skilled in the art will readily observe that numerous modifications and alterations of the device may be made while retaining the teachings of the invention. Accordingly, the above disclosure should be construed as limited only by the metes and bounds of the appended claims.

What is claimed is:

1. A method of creating a ROM code pattern on a photoresist layer, the method comprising:
providing a wafer having a photoresist layer coated on a top surface of the wafer;
providing a projection lens positioned atop the top surface of the wafer;
providing an exposure light source having a pre-selected wavelength for generating a dipole exposure ray; and
providing a ROM code mask positioned between the projection lens and the exposure light source, wherein the ROM code mask comprises a plurality of ROM code openings arranged in a non-periodic manner, and a plurality of assistant features arranged among the plurality of ROM code openings.

2. The method of claim 1 wherein the plurality of assistant features are used to increase image contrast of the plurality of ROM code openings.

3. The method of claim 1 wherein the pre-selected wavelength is approximately 248 nm.

4. The method of claim 1 wherein the pre-selected wavelength is approximately 193 nm.

5. The method of claim 1 wherein the pre-selected wavelength is approximately 157 nm.

6. The method of claim 1 wherein the projection lens has a numerical aperture (NA) that is greater than 0.4.

7. The method of claim 1 wherein the assistant features have a dimension such that that no corresponding image is formed on the photoresist layer after the dipole exposure ray passes through the assistant features.

8. The method of claim 1 wherein the assistant features function as image enhancement elements that render a combined pattern consisting of the plurality of ROM code openings and the plurality of assistant features that are substantially periodic along an x-axis.

9. A ROM code mask comprising:
a plurality of ROM code openings arranged in a non-periodic manner; and
a plurality of assistant features arranged among the plurality of ROM code openings;
wherein the assistant features function as image enhancement elements that render a combined pattern consisting of the plurality of ROM code openings and the plurality of assistant features that are substantially periodic along an x-axis.

10. The ROM code mask of claim 9 wherein the ROM code mask is utilized to create a ROM code pattern on a photoresist layer, a method of creating the ROM code pattern on the photoresist layer comprising:
providing a wafer having a photoresist layer coated on a top surface of the wafer;
providing a projection lens positioned atop the top surface of the wafer;
providing an exposure light source having a pre-selected wavelength for generating a dipole exposure ray; and
providing a ROM code mask positioned between the projection lens and the exposure light source.

11. The ROM code mask of claim 9 wherein the plurality of assistant features are used to increase image contrast of the plurality of ROM code openings.

12. The method of claim 10 wherein the pre-selected wavelength is approximately 248 nm.

13. The method of claim 10 wherein the pre-selected wavelength is approximately 193 nm.

14. The method of claim 10 wherein the pre-selected wavelength is approximately 157 nm.

15. The method of claim 10 wherein the projection lens has a numerical aperture (NA) that is greater than 0.4.
